(19) United States
(12) Patent Application Publication
(10) Pub. No.: US 2021/0020484 A1
(43) Pub. Date: Jan. 21, 2021

(54) APERTURE DESIGN FOR UNIFORMITY CONTROL IN SELECTIVE PHYSICAL VAPOR DEPOSITION

(71) Applicant: APPLIED MATERIALS, INC., Santa Clara, CA (US)

(72) Inventors: Keith Miller, Mountain View, CA (US); Farzad HOUSHMAND, Mountain View, CA (US); Prasoon SHUKLA, Bengaluru (IN)

(21) Appl. No.: 16/914,103

(22) Filed: Jun. 26, 2020

Related U.S. Application Data
(60) Provisional application No. 62/874,493, filed on Jul. 15, 2019.

(51) Int. Cl. H01L 21/677; H01L 21/673

(52) U.S. Cl. CPC H01L 21/67742; H01L 21/67748; H01L 21/67309

(57) ABSTRACT

Methods and apparatus for a PVD chamber are provided herein. In some embodiments, a selective PVD chamber includes a first housing surrounding a movable substrate support; a second housing adjacent the first housing; an opening disposed between the first housing and the second housing that partially exposes a top surface of the movable substrate support, wherein the opening includes a first curved side; and an elongate target disposed in the second housing to provide a stream of material flux from the elongate target into the first housing via the opening.

### CROSS-REFERENCE TO RELATED APPLICATIONS

This application claims benefit of U.S. provisional patent application Ser. No. 62/874,493, filed Jul. 15, 2019 which is herein incorporated by reference in its entirety.

### FIELD

Embodiments of the present disclosure generally relate to semiconductor processing.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD). However, the inventor has observed that with the drive to produce equipment to deposit more uniformly, certain applications may not be adequately served where purposeful deposition is required that is not symmetric or uniform with respect to the given structures being fabricated on a substrate.

Accordingly, the inventor has provided improved methods and apparatus for depositing materials via physical vapor deposition.

### SUMMARY

Methods and apparatus for a PVD chamber are provided herein. In some embodiments, a selective PVD chamber includes a first housing surrounding a movable substrate support; a second housing adjacent the first housing; an opening disposed between the first housing and the second housing that partially exposes a top surface of the movable substrate support, wherein the opening includes a first curved side; and an elongate target disposed in the second housing to provide a stream of material flux from the elongate target into the first housing via the opening.

In some embodiments, a selective PVD chamber includes a first housing surrounding a movable substrate support; a second housing adjacent the first housing with an opening disposed between the first housing and the second housing that partially exposes a top surface of the movable substrate support, wherein the opening includes a first curved side having a given radius and a second curved side opposite the first curved side having the given radius, and wherein the first curved side and second curved side both protrude towards a center of the opening; and a cylindrical target disposed in the second housing to provide a stream of material flux from the target into the first housing via the opening.

In some embodiments, a selective PVD chamber includes a first housing surrounding a movable substrate support; a second housing adjacent the first housing with an opening disposed between the first housing and the second housing that partially exposes a top surface of the movable substrate support, wherein the opening includes a curved side; a cylindrical target disposed in the second housing to provide a stream of material flux from the cylindrical target into the first housing via the opening; and a second cylindrical target disposed in the second housing to provide a stream of material flux from the cylindrical target into the first housing via the opening.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A is a schematic side view of an apparatus for physical vapor deposition in accordance with at least some embodiments of the present disclosure.

FIG. 1B is a schematic top view of an apparatus for physical vapor deposition in accordance with at least some embodiments of the present disclosure.

FIG. 2A is a schematic side view of a feature having a layer of material deposited thereon in accordance with at least some embodiments of the present disclosure.

FIG. 2B is a schematic side view of a substrate having a plurality of features having a layer of material deposited thereon, as depicted in FIG. 2A, in accordance with at least some embodiments of the present disclosure.

FIG. 2C is a schematic side view of a feature having a layer of material deposited thereon in accordance with at least some embodiments of the present disclosure.

FIG. 2D is a schematic side view of a substrate having a plurality of features having a layer of material deposited thereon, as depicted in FIG. 2C, in accordance with at least some embodiments of the present disclosure.

FIG. 3A is a schematic side view of an apparatus for physical vapor deposition in accordance with at least some embodiments of the present disclosure.

FIG. 3B is a schematic side view of an apparatus for physical vapor deposition in accordance with at least some embodiments of the present disclosure.

FIG. 4A is a schematic side view of an apparatus for physical vapor deposition illustrating material deposition angles in accordance with at least some embodiments of the present disclosure.

FIG. 4B is a schematic side view of an apparatus for physical vapor deposition illustrating material deposition angles in accordance with at least some embodiments of the present disclosure.

FIG. 5 is a partial top isometric view of an apparatus having a cylindrical target for physical vapor deposition in accordance with at least some embodiments of the present disclosure.

FIG. 6 is a partial top isometric view of an apparatus having a cylindrical target for physical vapor deposition in accordance with at least some embodiments of the present disclosure.

FIG. 7 is a schematic top view of an opening disposed between a first housing and a second housing in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for physical vapor deposition (PVD) are provided herein. Embodiments of the disclosed methods and apparatus advantageously enable uniform angular deposition of materials on a substrate. In such applications, deposited materials are asymmetric or angular with respect to a given feature on a substrate, but can be relatively uniform within all features across the substrate. Embodiments of the disclosed methods and apparatus advantageously enable new applications or opportunities for selective PVD of materials, thus further enabling new markets and capabilities.

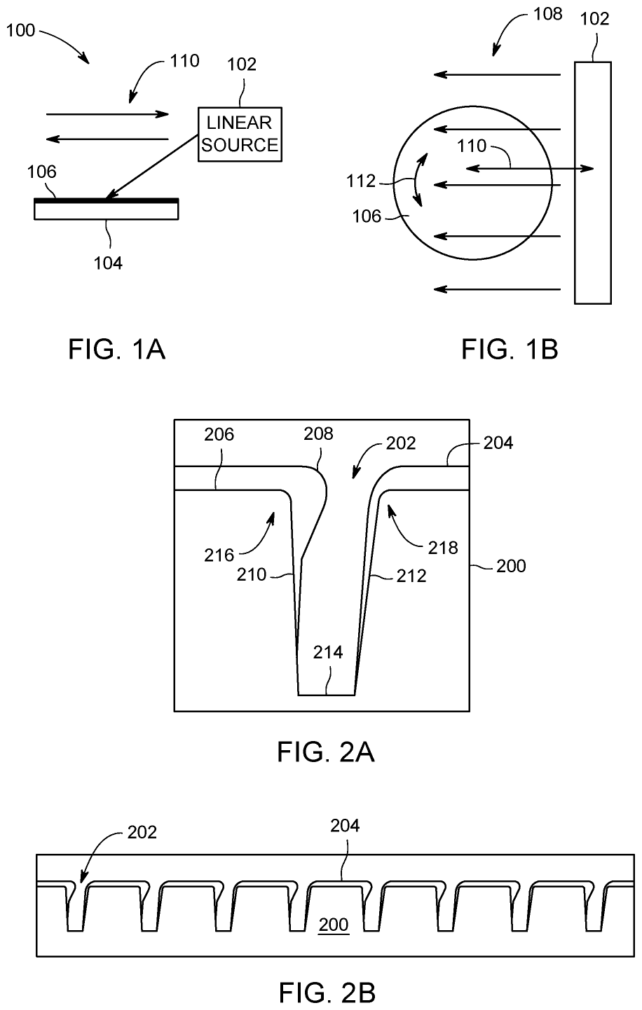

FIGS. 1A-1B are schematic side and top views, respectively, of an apparatus 100 for PVD in accordance with at least some embodiments of the present disclosure. Specifically, FIGS. 1A-1B schematically depict an apparatus 100 for PVD of materials on a substrate 106 at an angle to the generally planar surface of the substrate 106. The apparatus 100 generally includes a linear PVD source 102 and a substrate support 104 for supporting the substrate 106. The linear PVD source 102 is configured to provide a directed stream of material flux (stream 108 as depicted in FIGS. 1A-1B) from the source toward the substrate support 104 (and any substrate 106 disposed on the substrate support 104). The substrate support 104 has a support surface to support the substrate 106 such that a working surface of the substrate 106 to be deposited on is exposed to the directed stream 108 of material flux. The stream 108 of material flux provided by the linear PVD source has a width greater than that of the substrate support 104 (and any substrate 106 disposed on the substrate support 104). The stream 108 of material flux has a linear elongate axis corresponding to the width of the stream 108 of material flux. The substrate support 104 and the linear PVD source 102 are configured to move linearly with respect to each other, as indicated by arrows 110. The relative motion can be accomplished by moving either or both of the linear PVD source 102 or the substrate support 104. Optionally, the substrate support 104 may additionally be configured to rotate (for example, within the plane of the support surface), as indicated by arrows 112.

The linear PVD source 102 includes target material to be sputter deposited on the substrate 106. In some embodiments, the target material can be, for example, a metal, such as titanium, or the like, suitable for depositing titanium (Ti) or titanium nitride (TiN) on the substrate 106. In some embodiments, the target material can be, for example, silicon, or a silicon-containing compound, suitable for depositing silicon (Si), silicon nitride (SiN), silicon oxynitride (SiON), or the like on the substrate 106. Other materials may suitably be used as well in accordance with the teachings provided herein. The linear PVD source 102 further includes, or is coupled to, a power source (not shown) to provide suitable power for forming a plasma proximate the target material and for sputtering atoms off of the target material. The power source can be either or both of a DC or an RF power source. In some embodiments, the power source can be a pulsed DC power source.

Unlike an ion beam or other ion source, the linear PVD source 102 is configured to provide mostly neutrals and few ions of the target material. As such, a plasma may be formed having a sufficiently low density to avoid ionizing too many of the sputtered atoms of target material. For example, for a 300 mm diameter wafer as the substrate 106, about 1 to about 40 kW of DC or RF power may be provided. The power or power density applied can be scaled for other size substrates. In addition, other parameters may be controlled to assist in providing mostly neutrals in the stream 108 of material flux. For example, the pressure may be controlled to be sufficiently low so that the mean free path is longer than the general dimensions of an opening of the linear PVD source 102 through which the stream 108 of material flux passes toward the substrate support 104 (as discussed in more detail below). In some embodiments, the pressure may be controlled to be about 0.5 to about 5.0 millitorr.

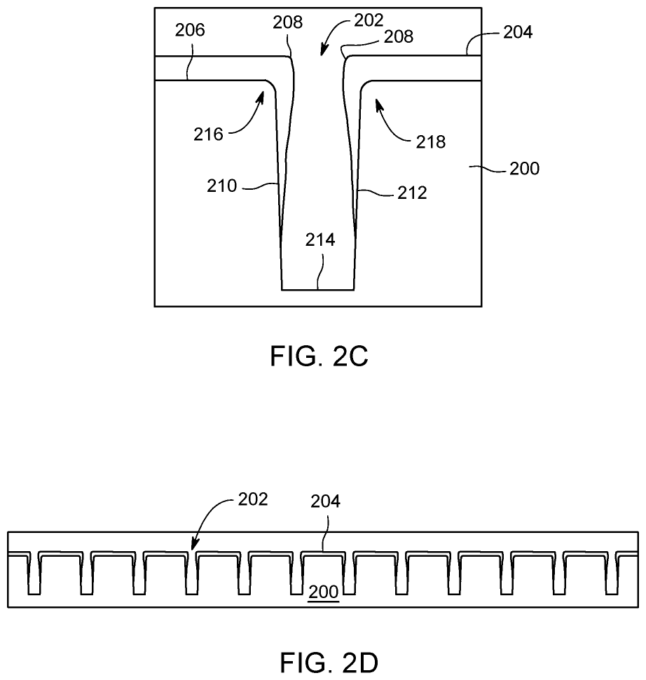

The methods and embodiments disclosed herein advantageously enable deposition of materials with a shaped profile, or in particular, with an asymmetric profile with respect to a given feature on a substrate, while maintaining overall deposition and shape uniformity across all features on a substrate. For example, FIG. 2A depicts a schematic side view of a substrate 200 including a feature 202 having a layer of material 204 deposited thereon in accordance with at least some embodiments of the present disclosure. The feature 202 can be a trench, a via, or dual damascene feature, or the like. In addition, the feature 202 can protrude from the substrate rather than extend into the substrate. The material 204 is deposited not just atop a top surface 206 of the substrate 200 (e.g., the field region), but also within or along at least portions of the feature 202 as well. However, the material 204 is deposited to a greater thickness on a first side 210 of the feature 202 as compared to an opposing second side 212 of the feature (as depicted by portion 208 of material). In some embodiments, and depending upon the incoming angle of the stream 108 of material flux, material can be deposited on a bottom 214 of the feature 202. In some embodiments, and as depicted in FIG. 2A, little or no material 204 is deposited on a bottom 214 of the feature 202. In some embodiments, additional material 204 is deposited particularly near an upper corner 216 of the first side 210 of the feature 202, as compared to an opposite upper corner 218 of the second side 212 of the feature 202.

As shown in FIG. 2B, which is a schematic side view of a substrate having a plurality of features having a layer of material 204 deposited thereon in accordance with at least some embodiments of the present disclosure, the material 204 is deposited relatively uniformly across a plurality of features 202 formed in the substrate 200. As shown in FIG. 2B, the shape of the deposited material 204 is substantially uniform from feature to feature across the substrate 200 but is asymmetric within any given feature 202. Thus, embodiments in accordance with the present disclosure advantageously provide controlled/uniform angular deposition of the material 204 on the substrate 200 with a substantially uniform amount of the material 204 deposited on a field region of the substrate 200.

In some embodiments, for example where the substrate support 104 is configured to rotate in addition to moving linearly with respect to the linear PVD source 102, different profiles of material 204 deposition can be provided. For example, FIG. 2C depicts a schematic side view of a substrate 200 including feature 202 having a layer of material 204 deposited thereon in accordance with at least some embodiments of the present disclosure. As described above with respect to FIGS. 2A-2B, the material 204 is deposited not just atop a top surface 206 of the substrate 200 (e.g., the field region), but also within or along at least portions of the feature 202 as well. However, in embodiments consistent with FIG. 2C, the material 204 is deposited to a greater thickness on both the first side 210 of the feature 202 as well as the opposing second side 212 of the feature 202 (as depicted by portion 208 of material) as compared to the bottom 214 of the feature 202. In some embodiments, and depending upon the incoming angle of the stream 108 of material flux, the amount of materials deposited on lower portions of the sidewall (e.g., the first side 210 and the second side 212) and the bottom 214 of the feature 202 can be controlled. However, as depicted in FIG. 2C, little or no material is deposited on the bottom 214 of the feature 202 (as well as on the lower portion of the sidewalls proximate the bottom 214).

As shown in FIG. 2D, which is a schematic side view of a substrate having a plurality of features having a layer of material deposited thereon in accordance with at least some embodiments of the present disclosure, the material 204 is deposited relatively uniformly across the plurality of features 202 formed in the substrate 200. As shown in FIG. 2D, the shape of the deposited material 204 is substantially uniform from feature to feature across the substrate 200, but with a controlled material profile within any given feature 202. Thus, embodiments in accordance with the present disclosure advantageously provide controlled/uniform angular deposition of material on a substrate with a substantially uniform amount of material deposited on a field region of the substrate 200.

Although the above description of FIGS. 2A-2D refer to the feature 202 having sides (e.g., the first side 210 and the second side 212), the feature 202 can be circular (such as a via). In such cases where the feature 202 is circular, although the feature 202 may have a singular sidewall, the first side 210 and second side 212 can be arbitrarily selected/controlled based upon the orientation of the substrate 200 (e.g., the substrate 106) with respect to the linear axis of movement of the substrate support 104 and direction of the stream 108 of material flux from the linear PVD source 102. Moreover, in embodiments where, for example, the substrate support 104 can rotate, the first side 210 and second side 212 can change, or be blended, dependent upon the orientation of the substrate 106 during processing.

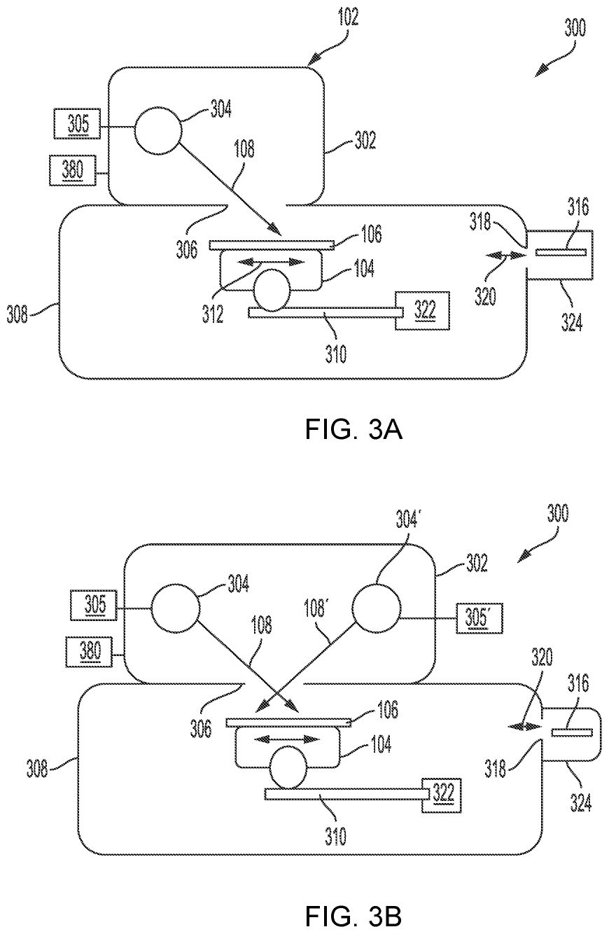

The above apparatus 100 can be implemented in numerous ways, and several non-limiting embodiments are provided herein in FIG. 3A through FIG. 7. While different Figures may discuss different features of the apparatus 100, combinations and variations of these features may be made in keeping with the teachings provided herein. In addition, although the Figures may show an apparatus having a particular orientation (e.g., vertical or horizontal), such orientations are examples and not limiting of the disclosure. For example, any configuration can be rotated or oriented differently than as shown in the Figures.

FIG. 3A is a two-dimensional schematic side views of an apparatus 300 for physical vapor deposition in accordance with at least some embodiments of the present disclosure. The apparatus 300 is an exemplary implementation of the apparatus 100 and discloses several exemplary features.

As depicted in FIG. 3A, the linear PVD source may include a chamber or housing 302 having an interior volume. A target 304 of source material to be sputtered is disposed within the housing 302. The target 304 is generally elongate and can be, for example, cylindrical or rectangular. The target 304 size can vary depending upon the size of the substrate 106 and the configuration of the processing chamber (e.g., deposition chamber 308, discussed below). For example, for processing a 300 mm diameter semiconductor wafer, the target 304 can be between about 100 to about 200 mm in width or diameter, and can have a length of about 400 to about 600 mm. The target 304 can be stationary or movable, including rotatable along the elongate axis of the target 304.

The target 304 is coupled to a power source 305. A gas supply 380 may be coupled to the interior volume of the housing 302 to provide a gas, such as an inert gas (e.g., argon) or nitrogen (N₂) suitable for forming a plasma within the interior volume when sputtering material from the target 304 (creating the stream 108 of material flux). The housing 302 is coupled to a deposition chamber 308 containing the substrate support 104. A vacuum pump can be coupled to an exhaust port (not shown) in at least one of the housing 302 or the deposition chamber 308 to control the pressure during processing. In some embodiments, the deposition chamber 308 may be referred to as a first housing and the housing 302 may be referred to as a second housing.

An opening 306 couples the interior volumes of the housing 302 and the deposition chamber 308 to allow the stream 108 of material flux to pass from the housing 302 into the deposition chamber 308, and onto the substrate 106. As discussed in more detail below, the position of the opening 306 with respect to the target 304 as well as the dimensions of the opening 306 can be selected or controlled to control the shape and size of the stream 108 of material flux passing though the opening 306 and into the deposition chamber 308. For example, the length of the opening is wide enough to allow the stream 108 of material flux to be wider than the substrate 106. In addition, the width of the opening 306 may be controlled to provide an even deposition rate along the length of the opening 306 (e.g., a wider opening may provide greater deposition uniformity, while a narrower opening may provide increased control over the angle of impingement of the stream 108 of material flux on the substrate 106). In some embodiments, a plurality of magnets may be positioned proximate the target 304 to control the position of the plasma with respect to the target 304 during processing. The deposition process can be tuned by controlling the plasma position (e.g., via the magnet position), and the size and relative position of the opening 306.

The housing 302 can include a liner of suitable material to retain particles deposited on the liner to reduce or eliminate particulate contamination on the substrate 106. The liner can be removable to facilitate cleaning or replacement. Similarly, a liner can be provided to some or all of the deposition chamber 308, for example, at least proximate the opening 306. The housing 302 and the deposition chamber 308 are typically grounded.

In the embodiment depicted in FIG. 3A, the linear PVD source 102 is stationary and the substrate support 104 is configured to linearly move. For example, the substrate support 104 is coupled to a linear slide 310 that can move linearly back and forth along direction of arrow 312 sufficiently within the deposition chamber 308 to allow the stream 108 of material flux to impinge upon desired portions of the substrate 106, such as the entire substrate 106. A position control mechanism 322, such as an actuator, motor, drive, or the like, controls the position of the substrate support 104, for example, via the linear slide 310. The substrate support 104 may be moved linearly along a plane such that the surface of the substrate 106 is maintained at a perpendicular distance of about 1 to about 10 mm from the opening 306. The substrate support 104 can be moved at a rate to control the deposition rate on the substrate 106. Alternatively, or additionally, the substrate support 104 can be coupled to robot linkage (not shown) that is configured to move the substrate support 104 linearly back and forth sufficiently within the deposition chamber 308 to allow the stream 108 of material flux to impinge upon desired portions of the substrate 106, such as the entire substrate 106.

Optionally, the substrate support 104 can also be configured to rotate within the plane of the support surface, such that the substrate 106 disposed on the substrate support 104 can be rotated. A rotation control mechanism, such as an actuator, a motor, a drive, a robot, or the like, controls the rotation of the substrate support 104 independent of the linear position of the substrate support 104. Accordingly, the substrate support 104 can be rotated while the substrate support 104 is also moving linearly through the stream 108 of material flux during operation. Alternatively, the substrate support 104 can be rotated between linear scans of the substrate support 104 through the stream 108 of material flux during operation (e.g., the substrate support 104 can be moved linearly without rotation and rotated while not moving linearly).

In addition, the substrate support 104 can move to a position for loading and unloading of substrates into and out of the deposition chamber 308. For example, in some embodiments, a transfer chamber 324, such as a load lock, may be coupled to the deposition chamber 308 via a slot or opening 318. A substrate transfer robot 316, or other similar suitable substrate transfer device, can be disposed within the transfer chamber 324 and movable between the transfer chamber 324 and the deposition chamber 308, as indicated by arrows 320, to move substrates into and out of the deposition chamber 308 (and onto and off of the substrate support 104). In embodiments where the substrate support 104 has a different orientation required for deposition and transfer, the substrate support 104 can further be rotatable or otherwise movable.

Depending upon the configuration of the substrate support 104, and in particular of the support surface of the substrate support 104 (e.g., vertical, horizontal, or angled), the substrate support 104 may be configured appropriately to retain the substrate 106 during processing. For example, in some embodiments, the substrate 106 may rest on the substrate support 104 via gravity. In some embodiments, the substrate 106 may be secured onto the substrate support 104, for example, via a vacuum chuck, an electrostatic chuck, mechanical clamps, or the like. Substrate guides and alignment structures may also be provided to improve alignment and retention of the substrate 106 on the substrate support 104.

Combinations and variations of the above embodiments include apparatus having more than one target to facilitate deposition at multiple angles. For example, FIG. 3B is a simplified schematic side view of an apparatus for physical vapor deposition in accordance with at least some embodiments of the present disclosure. In some embodiments, as depicted in FIG. 3B, the linear PVD source 102 includes target 304 and target 304′ in the housing 302. The target 304 and target 304′ can have respective streams 108, 108′ of material flux that are simultaneously or sequentially, directed through the opening 306 to impinge of the substrate 106. The target 304′ may be coupled to power source 305′ or power source 305.

In some embodiments, two linear PVD sources in respective housings may be provided such that one or more targets within each linear PVD source can have respective streams of material flux that are separately, e.g., simultaneously or sequentially, directed through respective openings to impinge of the substrate 106. The target materials can be the same material or different materials. In addition, process gases provided to the separate linear PVD sources can be the same or different. The size of the targets, location of the targets, location and size of the openings, can be independently controlled to independently control the impingement of materials from each stream 108, 108′ of material flux onto the substrate 106.

In each of the embodiments of FIGS. 3A-3B, the relative angles of the targets 304, 304′, and thus the direction of the streams 108, 108′ of material flux are illustrative and other angles can be chosen independently, including in directions such that the targets 304, 304′ are not parallel to each other.

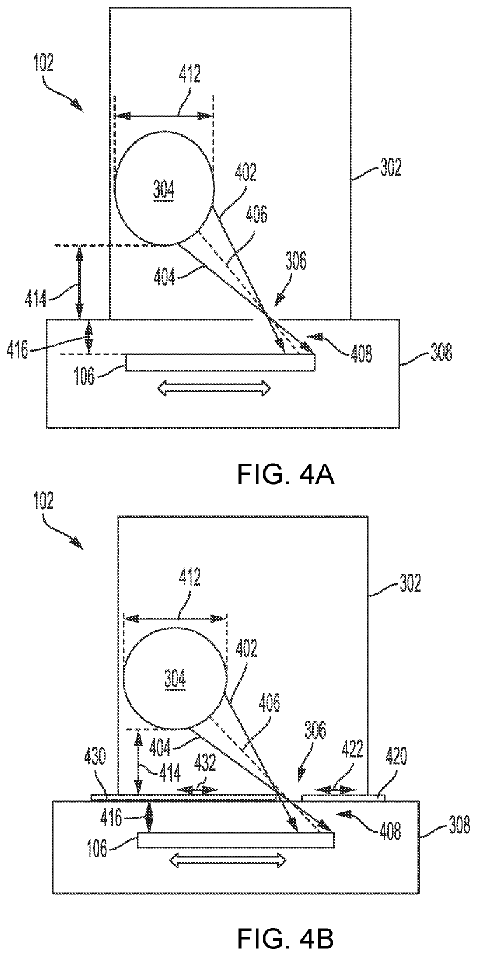

FIG. 4A is a schematic side view of an apparatus for physical vapor deposition illustrating material deposition angles in accordance with at least some embodiments of the present disclosure. The position of the target 304 within the housing 302 with respect to the opening 306 coupling the housing 302 to the deposition chamber 308 defines a general angle of incidence of the stream 108, as depicted by dashed line 406, in a plane orthogonal to the length of the opening 306 (e.g., in the plane of the page, where the opening 306 runs in a direction into and out of the page). However, the general angle of incidence is not the angle of incidence of all particles in the stream 108 of material flux, since the particles can come from different locations on the target and can generally travel through the opening along a line of sight from the location on the target where the particle originated. For example, arrows 402 and 404 show example boundaries of the stream 108 of material flux from the target that can pass through the opening. Particles travelling in other directions will not pass through the opening 306 and will be retained within the housing 302, and a portion 408 of the stream 108 of material flux that passes through the opening 306 impinges upon the substrate 106.

In some embodiments, at least one of the width of the opening or the position of the opening can be controlled to allow altering the relative position of the opening and the target within the housing. For example, FIG. 4B is a schematic side view of an apparatus for physical vapor deposition illustrating material deposition angles in accordance with at least some embodiments of the present disclosure. In some embodiments, at least one movable shutter is provided (two movable shutters 420, 430 shown in FIG. 4B) on the housing 302 and/or the deposition chamber 308. In some embodiments, the movable shutters 420, 430 have a shape corresponding to a shape of the opening 306. Movable shutters 420, 430 are movable linearly as indicated by arrows 422, 432. By control of one or both movable shutters 420, 430, the width of the opening 306 and/or the relative position of the opening 306 can be controlled. For example, moving one shutter, e.g., 420, with respect to the other shutter, e.g., 430, can change the width of the opening 306. Alternatively, moving both movable shutters 420, 430 together can change the position of the opening 306 with respect to the target 304 without altering the width of the opening 306. Alternatively, moving both movable shutters 420, 430 to different locations can change both the position and the width of the opening 306.

To control the size of the stream 108 of material flux, in addition to the angle of incidence, several parameters can be predetermined, selected, or controlled. For example, a diameter 412 or width of a target 304 can be predetermined, selected, or controlled. In addition, a first working distance 414 from the target 304 to a sidewall of the housing 302 containing the opening 306 (or to the movable shutters 420, 430), can be predetermined, selected, or controlled. A second working distance 416 from the opening 306 to the substrate 106 can also be predetermined, selected, or controlled. Lastly, the size of the opening 306 can be predetermined, selected, or controlled. Taking these parameters into account, the minimum and maximum angles of incidence can be predetermined, selected, or controlled. In addition, in embodiments with one or more movable shutters 420, 430, the movable shutters 420, 430 may be controlled to adjust the minimum and/or maximum angles of incidence of particles from the stream 108 of material flux.

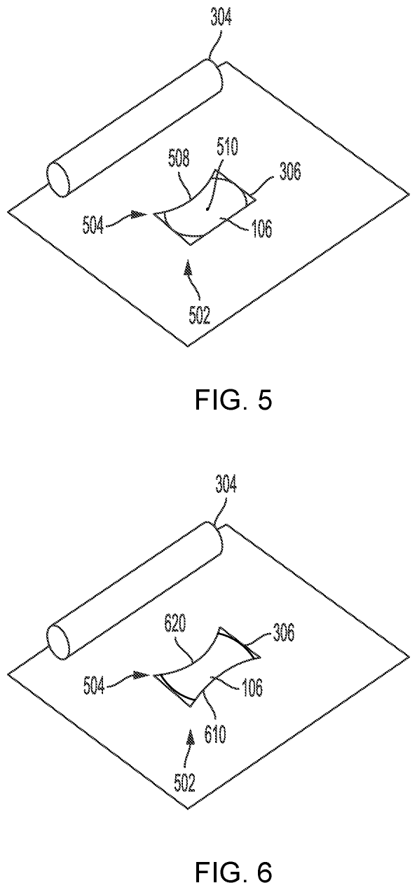

FIGS. 5 and 6 are partial top isometric views of an apparatus having a cylindrical target for physical vapor deposition in accordance with at least some embodiments of the present disclosure. As shown in FIGS. 5 and 6, the shape of the opening 306 may be used to further control which particles from the stream 108 of material flux pass through the opening 306 to impinge upon the substrate 106. The opening 306 includes a first side 502 and a second side 504 opposite the first side 502. In some embodiments, as shown in FIG. 5, the first side 502 of the opening 306 has a linear profile and the second side 504 has a curved profile 508. In some embodiments, a movable shutter provided on the housing 302 and/or the deposition chamber 308 has a curved profile corresponding with the curved profile 508. In some embodiments, as shown in FIG. 6, the first side 502 has a curved profile 610 and the second side 504 has a curved profile 620. In some embodiments, movable shutters provided on the housing 302 and/or the deposition chamber 308 have a curved profile corresponding with the curved profile 610 and curved profile 620, respectively. In some embodiments, the curved profiles 508, 610, 620 curve into the opening 306 (i.e., protrude towards a center 510 of the opening 306). In some embodiments, the curved profiles 508, 610, 620 extend from corners of the opening 306 towards the center 510 of the opening 306. The curved profiles 508, 610, 620 promote more uniform deposit thickness of the target material onto the substrate 106. For example, because the target 304 has a finite length, there may be greater deposit thickness at a central region of the substrate 106 versus the edge portions of the substrate 106 as the substrate 106 passes through the opening 306. The curved profiles 508, 610, 620 advantageously restrict particles from the stream 108 from impinging the central region of the substrate 106 so that there is more uniform deposit thickness of the target material across the substrate 106.

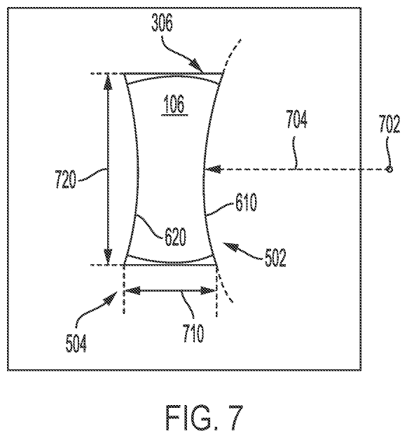

FIG. 7 is a schematic top view of the opening 306 disposed between a first housing (e.g., deposition chamber 308) and a second housing (e.g., housing 302) in accordance with some embodiments of the present disclosure. A size of the opening 306 is dependent on the size and location of the target 304 or targets 304, 304′ and the size of the substrate 106. The opening 306 has a length 720 and a width 710. In some embodiments, the width 710 is about 10 mm to about 250 mm. In some embodiments, the length 720 is greater than the width 710. For example, for a substrate 106 having a width of about 300 mm, the opening 306 may have a width 710 of about 170 mm to about 210 mm and a length 720 of about 300 mm to about 350 mm.

In some embodiments, the curved profile 610 has a radius 704 from a center 702 that corresponds with the width 710 and the length 720 of the opening 306. For example, the radius 704 is about 1.8 meters to about 2.1 meters for an opening 306 having a width 710 of about 170 mm to about 210 mm and a length 720 of about 300 mm to about 350 mm. In some embodiments, the radius 704 is generally constant across a length of the curved profile 610. In some embodiments, the curved profile 610 has a radius that varies across the length of the curved profile 610. In some embodiments, the radius 704 of the curved profile 610 on the first side 502 is the same as a radius of the curved profile 620 on the second side 504. In some embodiments, the radius 704 of the curved profile 610 on the first side 502 is the different than a radius of the curved profile 620 on the second side 504.

While the foregoing is directed to embodiments of the present disclosure, other and further embodiments of the disclosure may be devised without departing from the basic scope thereof.

1. A selective physical vapor deposition (PVD) chamber, comprising:
a first housing surrounding a movable substrate support;
a second housing adjacent the first housing;
an opening disposed between the first housing and the second housing that partially exposes a top surface of the movable substrate support, wherein the opening includes a first curved side; and
an elongate target disposed in the second housing to provide a stream of material flux from the elongate target into the first housing via the opening.

2. The selective PVD chamber of claim 1, wherein the opening includes a second curved side opposite the first curved side.

3. The selective PVD chamber of claim 1, wherein the opening is about 170 mm to about 210 mm wide.

4. The selective PVD chamber of claim 3, wherein the first curved side has a radius of about 1.8 meters to about 2.1 meters.

5. The selective PVD chamber of claim 1, wherein the first curved side has a radius corresponding to a width and length of the opening.

6. The selective PVD chamber of claim 1, wherein a length of the opening is greater than a width of the opening.

7. The selective PVD chamber of claim 1, further comprising a second elongate target disposed in the second housing to provide a stream of material flux from the second elongate target into the first housing via the opening.

8. The selective PVD chamber of claim 1, wherein the movable substrate support can rotate.

9. The selective PVD chamber of claim 1, wherein the movable substrate support is coupled to a linear slide configured to move the movable substrate support linearly.

10. A selective physical vapor deposition (PVD) chamber, comprising:
a first housing surrounding a movable substrate support;
a second housing adjacent the first housing with an opening disposed between the first housing and the second housing that partially exposes a top surface of the movable substrate support, wherein the opening includes a curved side;
a cylindrical target disposed in the second housing to provide a stream of material flux from the cylindrical target into the first housing via the opening; and
a movable shutter disposed on the first housing having a curved profile corresponding with the curved side.

11. The selective PVD chamber of claim 10, further comprising:
a second cylindrical target disposed in the second housing to provide a stream of material flux from the cylindrical target into the first housing via the opening.

12. The selective PVD chamber of claim 10, wherein the opening includes a second curved side opposite the curved side, wherein both the first curved side and the second curved side protrude towards a center of the opening.

13. The selective PVD chamber of claim 10, wherein the curved side has a radius corresponding to a width and length of the opening.

14. The selective PVD chamber of claim 10, wherein the movable shutter comprises two movable shutters that can change a position of the opening with respect to the cylindrical target without altering a width of the opening.

15. The selective PVD chamber of claim 10, wherein the movable shutter comprises two movable shutters that can move to different locations to change both a position and a width of the opening.

16. A selective physical vapor deposition (PVD) chamber, comprising:
a first housing surrounding a movable substrate support;
a second housing adjacent the first housing with an opening disposed between the first housing and the second housing that partially exposes a top surface of the movable substrate support, wherein the opening includes a first curved side having a given radius and a second curved side opposite the first curved side having the given radius, and wherein the first curved side and second curved side both protrude towards a center of the opening; and
a cylindrical target disposed in the second housing to provide a stream of material flux from the cylindrical target into the first housing via the opening.

17. The selective PVD chamber of claim 16, further comprising:
a second cylindrical target disposed in the second housing to provide a stream of material flux from the cylindrical target into the first housing via the opening.

18. The selective PVD chamber of claim 16, wherein the cylindrical target is made of titanium (Ti), titanium nitride (TiN), or a silicon-containing compound.

19. The selective PVD chamber of claim 16, wherein the given radius about 1.8 meters to about 2.1 meters.

20. The selective PVD chamber of claim 16, further comprising a movable shutter disposed on the first housing having a profile corresponding with the first curved side and the second curved side.
